(19) United States
(12) Patent Application Publication
(10) Pub. No.: US 2004/0008023 A1
(43) Pub. Date: Jan. 15, 2004

(54) Real-time charging electronic watthour meter

(76) Inventors: Moon-jong Jang, Deajun-shi (KR); Bong-jae Lee, Deajun-shi (KR)

Correspondence Address: SHLESINGER, ARKWRIGHT & GARVEY LLP, 3000 South Eads Street, Arlington, VA, 22202, US

(21) Appl. No.: 10/443,117

(22) Filed: May 22, 2003

Related U.S. Application Data
(63) Continuation of application No. PCT/KR02/02023, filed on Oct. 30, 2002.

(30) Foreign Application Priority Data
Oct. 30, 2001 (KR) 2001-0067261

(51) Int. Cl. G01R 7/00

(52) U.S. Cl. 324/142

(57) ABSTRACT

Disclosed is a real-time charging electronic watt-hour meter, which includes an electric power sensor for sensing the quantity of electric power used, a card reader into/from which a prepayment card is inserted/ejected, and a rate charging processor for calculating the power rate using the quantity of power used and a predetermined charging program and for deducting the power rate from the amount of the prepayment card, thereby charging the power rate in real time.

### FIELD OF THE INVENTION

The present invention relates to a watt-hour meter and a charging method for measuring the quantity of electric power used to charge the rate and, more particularly, to a real-time charging electronic watt-hour meter and a charging method capable of charging the power rate at the same time as electric power is being used.

### BACKGROUND OF THE INVENTION

With the conventional watt-hour meter, an electric power provider provides electricity to consumers and checks the quantity of electric power used at fixed periods, generally, by the month, to charge the power rate. FIG. 1 shows the configuration of the conventional watt-hour meter. As shown in FIG. 1, the conventional electronic watt-hour meter includes an analog signal sensor 100 for sensing voltage and current, an AD converter 110 for converting an analog signal into a digital signal, a central processing part 130 for processing the digital signal, a memory 120 for storing data and programs, a liquid crystal display 140 for displaying information such as the quantity of power used, a connection optical port 150 used for inspection of a meter in the place concerned and a communication node 160 used for remote connection.

Here, the central processing part 130 for processing digital signals can be composed of a single central processing unit according to a system construction technique. Otherwise, it can be composed of at least two central processing units that separately perform gauge examination and communication, and data processing.

Gauge examination may be remotely carried out but it is usually performed in the place concerned. Accordingly, the electric power provider does not easily collect the rate from temporary consumers or bad customers. Furthermore, the power rate is not paid or it is difficult to charge due to delay or evasion in payment of the power rate. Moreover, the rate cannot be charged timely when a notice for payment is not received by a corresponding recipient.

### OBJECTS AND SUMMARY OF THE INVENTION

An object of the present invention is to prevent the electric power provider from having difficulties in gauge examination and collection of the rate and problems caused by delay or evasion in payment of the power rate and to allow the electric power provider to easily check the quantity of power used and levy the rate. Another object of the present invention is to solve a problem that the power rate is not paid because a notice for payment is not delivered to a corresponding consumer timely and to solve inconvenience that the consumer must notice the electric power provider of a new address when he moves or he should pay the rate periodically.

To accomplish the objects of the present invention, there is provided a real-time charging electronic watt-hour meter, comprising an electric power sensor for sensing the quantity of electric power used; a card reader into/from which a prepayment card is inserted/ejected; and a rate charging processor for calculating the power rate using the quantity of power used and a predetermined charging program and for deducting the power rate from the amount of the prepayment card, thereby charging the power rate in real time.

### BRIEF DESCRIPTION OF THE DRAWINGS

Further objects and advantages of the invention can be more fully understood from the following detailed description taken in conjunction with the accompanying drawings, in which:

FIG. 1 shows the configuration of a conventional watt-hour meter;

FIG. 2 shows the configuration of a watt-hour meter according to the present invention;

FIG. 3 is a flow chart for showing an example of executing a rate charging program using a prepayment card;

FIG. 4 is a flow chart showing a step executed when the prepayment card is ejected;

FIG. 5 is a flow chart of calculating the charged amount in case of electric power for domestic use; and

FIG. 6 is a flow chart showing a method of calculating the industrial power rate, one of charging systems that apply different rates by seasons and time zones.

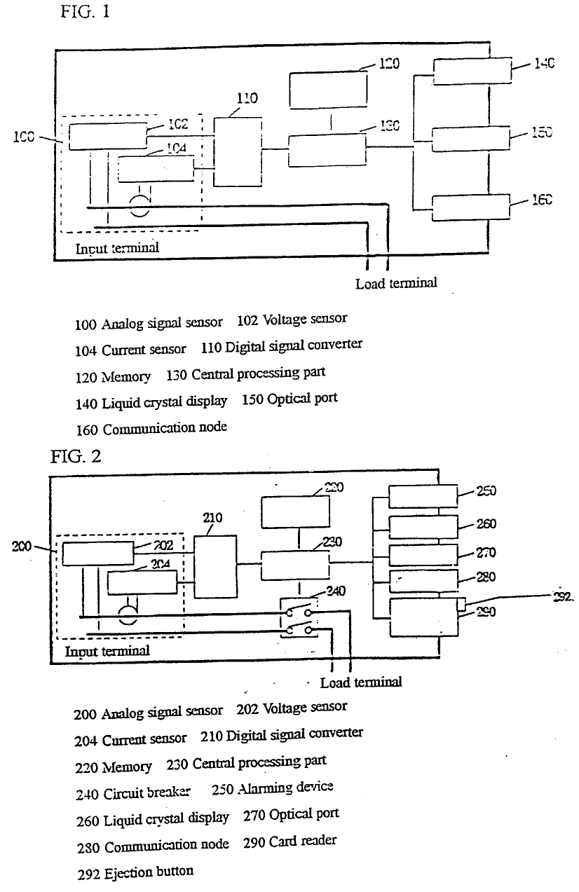

### DETAILED DESCRIPTION OF THE PREFERRED EMBODIMENTS

The present invention will now be described in detail in connection with preferred embodiments with reference to the accompanying drawings.

FIG. 2 shows the configuration of a watt-hour meter according to the present invention. As shown in FIG. 2, the watt-hour meter of the invention includes an analog signal sensor 200 for sensing voltage and current, an AD converter 210 for converting an analog signal into a digital signal, a central processing part 230 for processing the digital signal, a memory 220 of storing data and programs, a circuit breaker 240 for supplying a load or cutting off supply of load, a liquid crystal display 260 for displaying the quantity of power consumed, the power rate and the balance, an alarming device 250 for giving the alarm by steps when a prepaid amount of money becomes less than the balance, an optical port 270 used for connecting to the place concerned, a communication node 280 used for remote connection, a card reader 290 into which a prepayment card is inserted, and an ejection button 292 for ejecting the prepayment card from the card reader.

The central processing part 230 can be composed of a single central processing unit according to a system construction technique. Otherwise, it can be composed of at least two central processing units that separately perform gauge examination and communication, and data processing.

Especially, a rate calculation program required for supporting various charging systems can be installed in the memory 220 set inside the electronic watt-hour meter. The central processing part 230 calculates the rate according to the installed rate calculation program to charge the rate in real time.

In the configuration of FIG. 2, the analog sensor and the digital signal processing part can be integrated into an electric power sensor that senses the quantity of electric power consumed. In addition, the memory and the central processing part can be integrated into a rate charging processor that calculates the power rate using the quantity of power used and a predetermined charging program and deducts the power rate from the amount of the prepayment card.

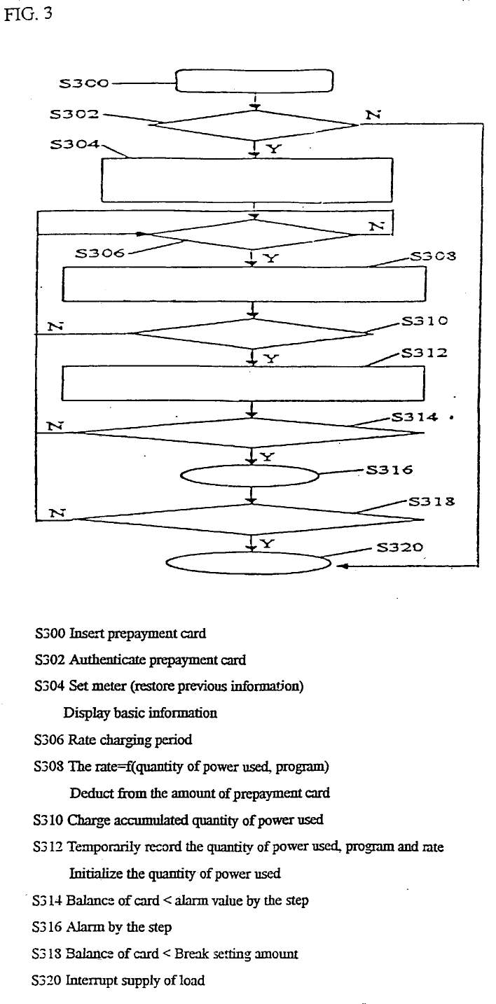

FIG. 3 is a flow chart for showing an example of executing the rate charging program using the prepayment card. Referring to FIG. 3, when the prepayment card is inserted into the watt-hour meter through the card reader 290 (S300), the central processing part 230 of the watt-hour meter confirms if the prepayment card is normal or not (S302). When the prepayment card is abnormal or there is no balance in the prepayment card, the confirmed result or the balance is displayed on the liquid crystal display 260 and the circuit breaker is opened to cut off the supply of electric power, finishing the operation (S320). When the prepayment card is normal, the state of the watt-hour meter is checked and, when there exists previous information, this information is used. When there is no previous information, the watt-hour meter is set to an initial value, and basic information is displayed on the liquid crystal display 260 (S304). A rate charging period is confirmed (S306) and, when charging is required, the rate is calculated using the rate calculation program stored in the memory 220 and the quantity of power used, and the calculated rate is deducted from the amount of the prepayment card (S308).

When the accumulated quantity of power used is charged in a situation other than the rate charging period (S310), the rate is charged according to a predetermined program stored in the memory 220 and the quantity of power used, the program, the rate and the date are recorded. Here, the quantity or power used is initialized (S312).

The balance of the card is compared with a predetermined alarm value by the step (S314). When the balance is less than the alarm value, an alarming sound by the step is given through the alarming device 250 (S316). Meanwhile, the balance of the card is compared with a predetermined break setting amount (S318), and the circuit breaker 240 is opened to interrupt the supply of electric power, finishing the operation when the balance is less than the break setting amount (S320).

In the aforementioned example of executing the rate charging program using the prepayment card shown in FIG. 3, each step can be selectively omitted according to a purpose.

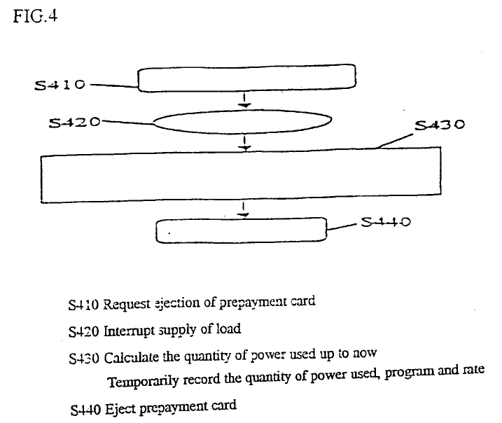

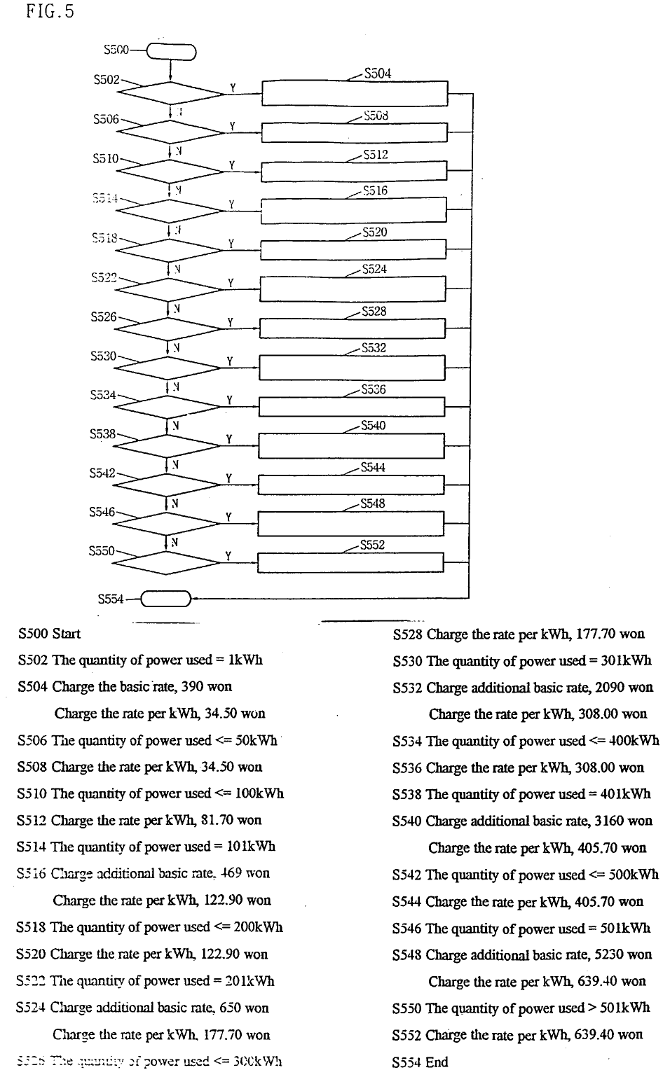

FIG. 4 is a flow chart showing a step executed when the prepayment card is ejected. Referring to FIG. 4, when a user pushes the ejection button 292 in order to eject the prepayment, requesting ejection of the prepayment card (S410), supply of a load is interrupted (S420) and the quantity of power consumed up to now is calculated using a predetermined program stored in the memory 220, and then the quantity of power used, the rate calculation program, the power rate and the date are temporarily recorded (S430). This record is information that is restored when the user inserts the prepayment card to resume the use of electric power. This information is required for accuracy in the calculation of the rate at a fixed rate or progressive rate for a specific period of time. After the recording step, the prepayment card is ejected from the watt-hour meter (S440).

Korea electric power corporation employs various rate calculation methods according to types of consumers, such as electric power for domestic use, general electric power, electric power for educational use, industrial electric power and so on. Accordingly, the real-time charging electronic watt-hour meter must be able to calculate the power rate according to an applied power rate system. The power rate calculation program is stored in the memory 220 and, when the program is required, the central processing part 230 fetches it to calculate the charged rate according to the quantity of power consumed.

FIG. 5 is a flow chart of calculating a charged amount of money in case of electric power for domestic use. As shown in FIG. 5, upon the start of inspection of the meter (S500), the basic rate, 390 won, and the rate per kWh, 34.50 won, are charged (S504) when the quantity of power used becomes 1 kWh (S502). The rate per kWh, 34.50 won, is charged (S508) while the quantity of power used is less than 50 kWh (S506), and the rate per kWh, 81.70 won, is charged (S512) while the quantity of power used is less than 100 kWh (S510).

The additional basic rate, 460 won, and the rate per kWh, 122.90 won, are charged (S516) when the quantity of power used becomes 101 kWh (S514), and the rate per kWh, 122.90 won, is charged (S520) while the quantity of power used is less than 200 kWh (S518).

The additional basic rate, 640 won, and the rate per kWh, 177.70 won, are charged (S524) when the quantity of power used becomes 201 kWh (S522), and the rate per kWh, 177.70 won, is charged (S528) while the quantity of power used is less than 300 kWh (S526).

The additional basic rate, 460 won, and the rate per kWh, 122.90 won, are charged (S516) when the quantity of power used becomes 101 kWh (S514), and the rate per kWh, 122.90 won, is charged (S520) while the quantity of power used is less than 200 kWh (S518).

The additional basic rate, 460 won, and the rate per kWh, 122.90 won, are charged (S516) when the quantity of power used becomes 101 kWh (S514), and the rate per kWh, 122.90 won, is charged (S520) while the quantity of power used is less than 200 kWh (S518).

The additional basic rate, 2090 won, and the rate per kWh, 308.00 won, are charged (S532) when the quantity of power used becomes 301 kWh (S530), and the rate per kWh, 308.00 won, is charged (S536) while the quantity of power used is less than 400 kWh (S534).

The additional basic rate, 3160 won, and the rate per kWh, 405.70 won, are charged (S540) when the quantity of power used becomes 401 kWh (S538), and the rate per kWh, 405.70 won, is charged (S544) while the quantity of power used is less than 500 kWh (S542).

In the final step, the additional basic rate, 5230 won, and the rate per kWh, 639.40 won, are charged (S548) when the quantity of power used becomes 501 kWh (S546), and the rate per kWh, 639.40 won, is charged (S552) when the quantity of power used exceeds 501 kWh (S550).

According to the above-described steps, the power rate calculated by employing a progressive rate, such as the power rate in case of electric power for domestic use, can be charged in real time.

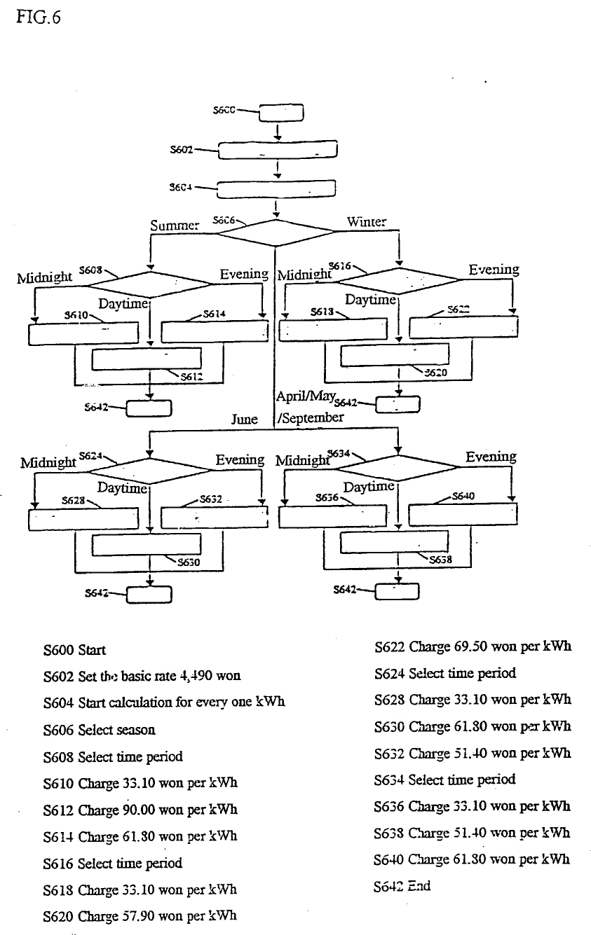

In case of the power rate, Korea electric power corporation employs various methods of calculating the rate in proportion to the quantity of power consumed. FIG. 6 is a flow chart showing a method of calculating the industrial power rate, one of charging systems that apply different rates by seasons and time zones.

Referring to FIG. 6, upon the start of execution of the rate calculation program (S600), the basic rate, 4,490 won, is set (S602) and a point at which calculation is started for every one kWh is fixed (S604). The current season is selected (S606) to go a step corresponding to summer, winter, June or April/May/September.

When the current season is summer, the process goes to the step S608 to select a period of time. When the current season is winter, the process goes to the step S616 to select a period of time. The process goes to the step S624 to select a period of time when the current season is June and goes to the step S634 to select a period of time in case of April/May/September.

In the step S608 corresponding to summer, 33.10 won is charged per kWh (S610) when the current time is midnight, 90.00 won is charged per kWh (S612) in the daytime, and 61.80 won is charged per kWh (S614) in the evening.

In the step S616 corresponding to winter, 33.10 won is charged per kWh (S618) when the current time is midnight, 57.90 won is charged per kWh (S620) in the daytime, and 69.50 won is charged per kWh (S622) in the evening.

In the step S624 corresponding to June, 33.10 won is charged per kWh (S628) when the current time is midnight, 61.80 won is charged per kWh (S630) in the daytime, and 51.40 won is charged per kWh (S632) in the evening.

In the step S634 corresponding to April/May/September, 33.10 won is charged per kWh (S636) when the current time is midnight, 51.40 won is charged per kWh (S638) in the daytime, and 61.80 won is charged per kWh (S640) in the evening.

When the charging per kWh is finished, the operation is completed (S642), waiting for the next one kWh. The operation is resumed when the quantity of power used becomes 1 kWh again (S604).

According to the present invention constructed as above, the electric power provider can charge the power rate at the same time as it provides electric power. Accordingly, the provider can easily check the quantity of power used and collect the rate even from a temporary consumer or bad customer. In addition, the present invention can solve difficulties in timely charging due to delay or evasion in payment of the power rate so that the electric power provider can increase a sale and profit. Furthermore, the operation of checking the quantity of power consumed in advance for collecting the power rate becomes unnecessary and the operation of levying the power rate is replaced by an operation of issuing the prepayment card or similar operations so that the quantity of operations is reduced.

In case of consumers, it is possible to solve the problem that the power rate is in arrears because a notice of payment is not received timely and inconvenience of informing the electric power provider of a new address when a consumer moves and periodically paying the power rate. In addition, the present invention can provide various charging systems to consumers because the rate calculation program can be changed if required.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A real-time charging electronic watt-hour meter, comprising:
an electric power sensor for sensing the quantity of electric power used;
a card reader into/from which a prepayment card is inserted/ejected; and
a rate charging processor for calculating the power rate using the quantity of power used and a predetermined charging program and for deducting the power rate from the amount of the prepayment card, thereby charging the power rate in real time.

2. The real-time charging electronic watt-hour meter as claimed in claim 1, further comprising a display for displaying the balance of the prepayment card, the quantity of power used and the power rate.

3. The real-time charging electronic watt-hour meter as claimed in claim 1, further comprising an alarming device for giving an alarm sound when the balance of the prepayment card is less than a predetermined amount by the step, the alarming device giving the alarm sound at each step.

4. The real-time charging electronic watt-hour meter as claimed in claim 1, further comprising a concerned place connection port capable of accessing the rate charging processor in order to input or correct the charging program in the place concerned.

5. The real-time charging electronic watt-hour meter as claimed in claim 1, further comprising a remote communication connection port capable of accessing the rate charging processor in order to input or correct the charging program remotely.
